(19) United States
(12) Patent Application Publication
(10) Pub. No.: US 2022/0130026 A1
(43) Pub. Date: Apr. 28, 2022

(54) WIRE NON-ATTACHMENT INSPECTION SYSTEM, WIRE NON-ATTACHMENT DETECTION DEVICE, AND WIRE NON-ATTACHMENT DETECTION METHOD

(71) Applicant: SHINKAWA LTD., Tokyo (JP)

(72) Inventors: Michael KIRKBY, Tokyo (JP); Takaya KINJO, Tokyo (JP); Hiroshi MUNAKATA, Tokyo (JP)

(73) Assignee: SHINKAWA LTD., Tokyo (JP)

(21) Appl. No.: 17/428,963

(22) PCT Filed: Mar. 12, 2020
(86) PCT No.: PCT/JP2020/010693

§ 371 Date: Aug. 5, 2021

(30) Foreign Application Priority Data
Mar. 13, 2019 (JP) 2019-046296

(51) Int. Cl. G06T 7/00; H04N 7/18; H04R 1/02

(52) U.S. Cl. CPC G06T 7/001; H01L 25/0657; H04R 1/028; H04N 7/183

(57) ABSTRACT

The present invention provides a wire non-attachment inspection system (100) of a semiconductor device (10), wherein: the wire non-attachment inspection system (100) comprises an ultrasonic oscillator (40), an ultrasonic transducer (42), a camera (45), a display (48), and a control unit (50); and the control unit (50) calculates the difference in image between one frame of a captured video and a previous frame before the one frame, and displays, on the display, an image of a wire for which the difference exceeds a prescribed threshold value so as to be displayed differently than the image of another wire.

### BACKGROUND

### Technical Field

The present invention relates to a wire non-attachment inspection system, a wire non-attachment detection device, and a wire non-attachment detection method for detecting non-attachment of a wire connecting an electrode of a semiconductor element mounted on a substrate and an electrode of the substrate.

### Background Art

A wire bonding apparatus connecting an electrode of a substrate and an electrode of a semiconductor chip by a wire is used frequently. In the wire bonding apparatus, a method of detecting non-attachment between the electrode of the semiconductor chip and the wire by an electrical member that allows a current to flow between the wire and the semiconductor chip is used (for example, see Patent Literature 1).

Further, in the wire bonding apparatus, a method of detecting non-attachment between the electrode of the semiconductor chip and the wire by a mechanical member that detects a displacement in the Z direction from the landing of the capillary to the end of bonding is used (for example, see Patent Literature 2).

### CITATION LIST

### Patent Literature

### [Patent Literature 1]

Japanese Patent Laid-Open No. 9-213752

### [Patent Literature 2]

Japanese Patent Laid-Open No. 2010-56106

### SUMMARY

### Technical Problem

Incidentally, in recent years, there has been a demand for higher accuracy in detecting non-attachment of wires. However, the detection of non-attachment by the electrical member or the mechanical member described in Patent Literatures 1 and 2 may cause erroneous detection.

Further, it is required to detect non-attachment of all wires connecting the electrode of the semiconductor chip and the electrode of the substrate. However, in the non-attachment detection methods described in Patent Literatures 1 and 2, since the non-attachment is detected for each wire, there is a problem that inspection takes a long time, for example, in a semiconductor chip having 100 or more wires connecting one semiconductor chip and a substrate.

Here, an objective of the present invention is to provide a wire non-attachment inspection system capable of highly accurately detecting non-attachment of a wire in a short time.

### Solution to Problem

A wire non-attachment inspection system of the present invention is a wire non-attachment inspection system of a semiconductor device including a substrate, a semiconductor element mounted on the substrate, and a wire connecting an electrode of the semiconductor element to an electrode of the substrate or connecting one electrode of the semiconductor element to another electrode of the semiconductor element, the wire non-attachment inspection system including: an ultrasonic oscillator; an ultrasonic vibrator which is connected to the ultrasonic oscillator and ultrasonically vibrates the semiconductor device by power from the ultrasonic oscillator; a camera which captures a video of the semiconductor device; a display which displays the video captured by the camera; and a control unit which adjusts the ultrasonic oscillator and analyzes the video captured by the camera, wherein the control unit calculates a difference in image between one frame of a captured video and a previous frame before the one frame and displays an image of the wire for which the difference exceeds a prescribed threshold value on the display so as to be displayed different from the image of another wire.

When each wire is ultrasonically vibrated by vibrating the semiconductor device with ultrasonic waves, the amplitude of the non-attached wire becomes larger than the amplitude of the normally connected wire. Therefore, when a difference in image between one frame of the captured video and the previous frame before the one frame is calculated and the image of the wire for which the difference in image exceeds a prescribed threshold value, that is, the non-attached wire is displayed on the display so as to be displayed different from the image of another wire, the image of the non-attached wire can be displayed on the display so as to be distinguished from another image. Accordingly, the inspector can detect the non-attached wire by the image displayed on the display. Since a difference between the amplitude of the non-attached wire and the amplitude of the normally connected wire is noticeable, the non-attachment of the wire can be detected with high accuracy. Further, since the images of all wires included in the semiconductor device are acquired by the camera and are analyzed and displayed on the display, it is possible to inspect the non-attachment of all wires in a short time even when the number of the wires increases.

In the wire non-attachment inspection system of the present invention, the control unit may display an image of an excess region for which the difference exceeds a prescribed threshold value in a vibration region of the wire on the display so as to be displayed different from an image of another region.

When the image of a certain region is displayed differently in this way, an area or region for displaying another image increases and the inspector can easily detect the non-attached wire.

In the wire non-attachment inspection system of the present invention, the control unit may calculate the difference by changing the number of frames between one frame for calculating the difference and a previous frame or a frame rate of a video.

Accordingly, the difference can be noticeably detected by adjusting the timing of the frame of the video that calculates the difference and the vibration frequency of the wire.

In the wire non-attachment inspection system of the present invention, the control unit may ultrasonically vibrate the semiconductor device with the ultrasonic vibrator by changing an oscillation frequency of the ultrasonic oscillator.

The natural frequency of the wire changes depending on the length of the wire between the bonding points and the diameter of the wire. Therefore, when the oscillation frequency of the ultrasonic oscillator is changed and the semiconductor device is ultrasonically vibrated by the ultrasonic vibrator, it is possible to inspect the non-attachment of a plurality of wires having different lengths of the wires between the bonding points or different diameters of the wires. Accordingly, it is possible to inspect the non-attachment of another wire having a different length or diameter in a short time.

In the wire non-attachment inspection system of the present invention, the ultrasonic vibrator may be an ultrasonic transducer which is connected to the substrate of the semiconductor device and ultrasonically vibrates the substrate.

Accordingly, it is possible to provide the wire non-attachment inspection system capable of highly accurately detecting the non-attachment of the wire in a short time with a simple configuration.

In the wire non-attachment inspection system of the present invention, the ultrasonic vibrator may be an ultrasonic speaker which is disposed in the periphery of the semiconductor device.

Accordingly, it is possible to directly and ultrasonically vibrate the wire and more highly accurately detect the non-attachment of the wire.

A wire non-attachment detection device of the present invention is a wire non-attachment detection device of a semiconductor device including a substrate, a semiconductor element mounted on the substrate, and a wire connecting an electrode of the semiconductor element to an electrode of the substrate or connecting one electrode of the semiconductor element to another electrode of the semiconductor element, the wire non-attachment detection device including: an ultrasonic oscillator; an ultrasonic vibrator which is connected to the ultrasonic oscillator and ultrasonically vibrates the semiconductor device by power from the ultrasonic oscillator; a camera which captures a video of the semiconductor device; and a control unit which adjusts the ultrasonic oscillator and analyzes the video captured by the camera, wherein the control unit calculates a difference in image between one frame of a captured video and a previous frame before the one frame and outputs a non-attachment detection signal when the difference exceeds a prescribed threshold value.

When each wire is ultrasonically vibrated by vibrating the semiconductor device with ultrasonic waves, the amplitude of the non-attached wire becomes larger than the amplitude of the normally connected wire. Therefore, if a difference in image between one frame of the captured video and the previous frame before the one frame is calculated, it is possible to detect the non-attachment of the wire when the difference in image exceeds a prescribed threshold value. Since a difference between the amplitude of the non-attached wire and the amplitude of the normally connected wire is noticeable, it is possible to highly accurately detect the non-attachment of the wire. Further, since the images of all wires included in the semiconductor device are acquired by the camera and the difference in image can be analyzed, it is possible to detect the non-attachment of the wire in the entire semiconductor device in a short time even when the number of the wires increases.

In the wire non-attachment detection device of the present invention, the control unit may calculate the difference by changing the number of frames between one frame for calculating the difference and a previous frame or a frame rate of a video.

Accordingly, since it is possible to noticeably detect the difference by adjusting the timing of the frame of the video that calculates the difference and the vibration frequency of the wire, it is possible to improve the accuracy of the non-attachment detection.

In the wire non-attachment detection device of the present invention, the control unit may ultrasonically vibrate the semiconductor device with the ultrasonic vibrator by changing an oscillation frequency of the ultrasonic oscillator.

Accordingly, it is possible to detect the non-attachment of another wire having a different length or diameter in a short time.

In the wire non-attachment detection device of the present invention, the ultrasonic vibrator may be an ultrasonic transducer which is connected to the substrate of the semiconductor device and ultrasonically vibrates the substrate or may be an ultrasonic speaker which is disposed in the periphery of the semiconductor device.

Since the ultrasonic transducer is used, it is possible to highly accurately detect the non-attachment of the wire in a short time with a simple configuration. Further, since the ultrasonic speaker is used, it is possible to directly and ultrasonically vibrate the wire and more highly accurately detect the non-attachment of the wire.

A wire non-attachment detection method of the present invention is a wire non-attachment detection method of a semiconductor device including a substrate, a semiconductor element mounted on the substrate, and a wire connecting an electrode of the semiconductor element to an electrode of the substrate or connecting one electrode of the semiconductor element to another electrode of the semiconductor element, the wire non-attachment detection method including: a preparation step of preparing an ultrasonic oscillator, an ultrasonic vibrator which is connected to the ultrasonic oscillator and ultrasonically vibrates the semiconductor device by power from the ultrasonic oscillator, a camera which captures a video of the semiconductor device, and a control unit which is connected to the ultrasonic oscillator and the camera; an ultrasonic vibration step of ultrasonically vibrating the substrate with the ultrasonic vibrator by power from the ultrasonic oscillator; a capturing step of capturing a video of the ultrasonically vibrated semiconductor device by the camera; a difference calculation step of calculating a difference in image between one frame of the captured video and a previous frame before the one frame; and a non-attachment detection step of detecting non-attachment of a wire when the difference exceeds a prescribed threshold value.

Accordingly, it is possible to highly accurately detect the non-attachment of the wire. Further, it is possible to detect the non-attachment of all wires in a short time even when the number of the wires increases.

In the wire non-attachment detection method of the present invention, the preparation step may include a step of preparing a display displaying a video captured by the camera and connecting the display to the control unit, the wire non-attachment detection method may further include a display step of displaying an image of the wire for which the difference exceeds a prescribed threshold value on the display so as to be displayed different from the image of another wire, and the non-attachment detection step may be to detect non-attachment of the wire based on an image displayed on the display.

Accordingly, the inspector can detect the non-attached wire by the image displayed on the display.

In the wire non-attachment detection method of the present invention, an image of an excess region for which the difference exceeds a prescribed threshold value in a vibration region of the wire may be displayed on the display so as to be displayed different from an image of another region.

Accordingly, since an area or region for displaying another image increases, the inspector can easily detect the non-attached wire.

### Advantageous Effects of Invention

The present invention can provide a wire non-attachment inspection system capable of highly accurately detecting non-attachment of a wire in a short time.

### BRIEF DESCRIPTION OF THE DRAWINGS

FIG. 1 is a system diagram showing a configuration of a wire non-attachment inspection system of an embodiment.

FIG. 2 is a plan view showing an image captured by a camera.

FIG. 3 is a flowchart showing an operation of a control unit of the wire non-attachment inspection system shown in FIG. 1.

FIG. 4(a) is an enlarged plan view of a part A of FIG. 3 when a substrate is ultrasonically vibrated and FIG. 4(b) is an enlarged plan view of a part B shown in FIG. 4(a).

FIG. 5 is a plan view showing an excess region when the substrate is ultrasonically vibrated.

FIG. 6 is a system diagram showing a configuration of a wire non-attachment inspection system of another embodiment.

FIG. 7 is a system diagram showing a configuration of a wire non-attachment detection device of an embodiment.

FIG. 8 is a flowchart showing an operation of the wire non-attachment detection device shown in FIG. 7.

### DESCRIPTION OF THE EMBODIMENTS

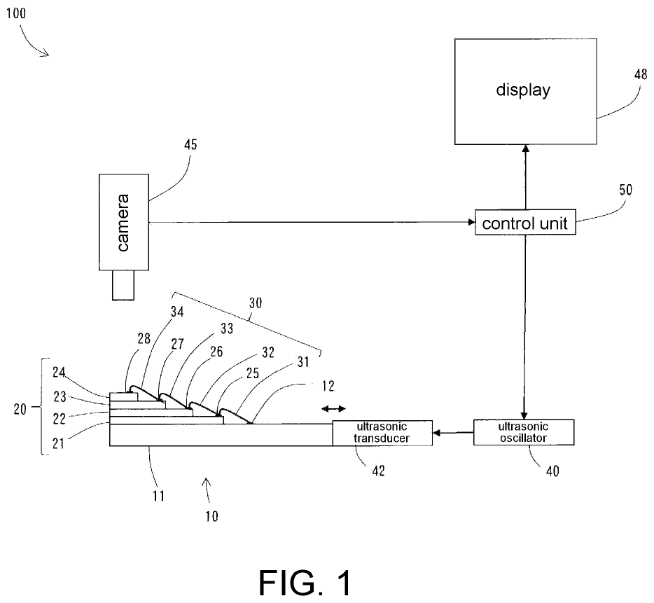

Hereinafter, a wire non-attachment inspection system 100 of an embodiment will be described with reference to the drawings. As shown in FIG. 1, the wire non-attachment inspection system 100 is used to inspect non-attachment between a wire 30 of a semiconductor device 10 and an electrode 12 of a substrate 11 or electrodes 25 to 28 of the semiconductor device 10. The wire non-attachment inspection system 100 includes an ultrasonic oscillator 40, an ultrasonic transducer 42 which is an ultrasonic vibrator, a camera 45, a display 48, and a control unit 50.

The semiconductor device 10 which is an inspection target of the wire non-attachment inspection system 100 has a configuration in which semiconductor chips 21 to 24 are laminated and mounted on the substrate 11 in four stages and electrodes 25 to 28 of the semiconductor chips 21 to 24 and the electrode 12 of the substrate 11 are continuously connected by one wire 30. Here, the semiconductor chips 21 to 24 constitute a semiconductor element 20. One wire 30 includes a first-stage wire 31 which connects the electrode 25 of the first-stage semiconductor chip 21 to the electrode 12 of the substrate 11 and second-stage to fourth-stage wires 32 to 34 which respectively connect the electrodes 26 to 28 of the second-stage to fourth-stage semiconductor chips 22 to 24 to the electrodes 25 to 27 of the first-stage to third-stage semiconductor chips 21 to 23.

The ultrasonic oscillator 40 outputs AC power having a frequency in an ultrasonic region and ultrasonically vibrates the ultrasonic transducer 42. The ultrasonic transducer 42 is a member that is driven by AC power in a frequency region of an ultrasonic wave input from the ultrasonic oscillator 40 and is ultrasonically vibrated. For example, the ultrasonic oscillator may be configured as a piezo element or the like. The ultrasonic transducer 42 is connected to the substrate 11 of the semiconductor device 10.

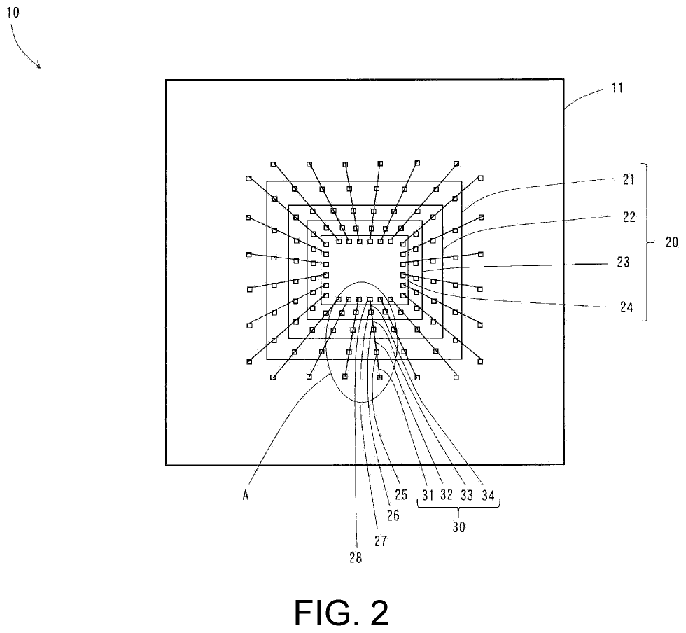

As shown in FIG. 1, the camera 45 is disposed above the semiconductor device 10 and captures the image of the wires 30 continuously connected to the substrate 11, the semiconductor chips 21 to 24 mounted on the substrate 11, the electrodes 25 to 28 disposed on the outer peripheral portions of the semiconductor chips 21 to 24, the electrode 12 of the substrate 11 disposed in the periphery of the first-stage semiconductor chip 21, and the electrodes 12 and 25 to 28 as shown in FIG. 2. The camera 45 captures an image of a video and outputs the image to the control unit 50.

The display 48 is an image display device that displays a video captured by the camera 45.

The control unit 50 is a computer that includes a CPU and a storage unit therein. The ultrasonic oscillator 40 is connected to the control unit 50 and is operated by an instruction of the control unit 50. Further, the control unit 50 adjusts the camera 45, analyzes the video captured by the camera 45, and outputs the result to the display 48.

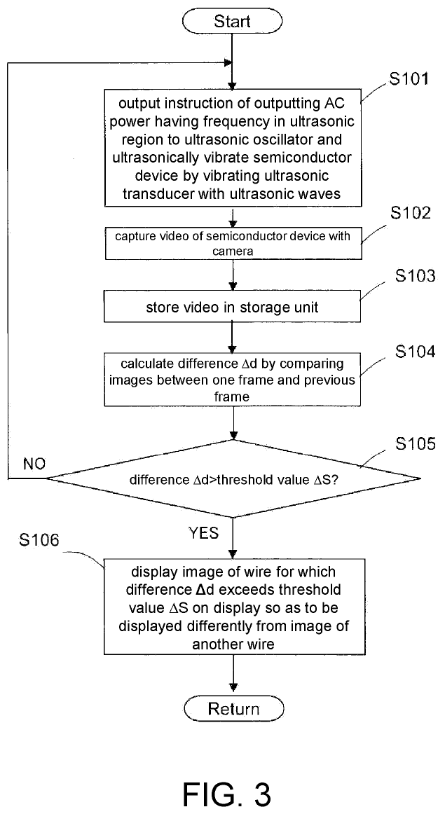

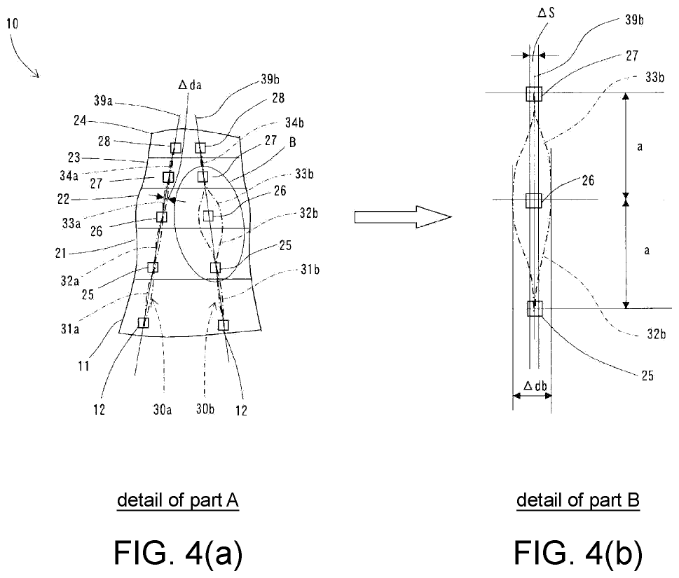

Hereinafter, the operation of the wire non-attachment inspection system 100 will be described with reference to FIGS. 3 and 4. As shown in step S101 of FIG. 3, the control unit 50 outputs an instruction of outputting AC power having a frequency in an ultrasonic region to the ultrasonic oscillator 40. According to this instruction, the ultrasonic oscillator 40 outputs AC power of a predetermined frequency, for example, a frequency of about 40 kHz. The AC power output by the ultrasonic oscillator 40 is input to the ultrasonic transducer 42 and the ultrasonic transducer 42 is ultrasonically vibrated. The ultrasonic transducer 42 vibrates the substrate 11 of the semiconductor device 10 by ultrasonic vibration, so that each wire 30 of the semiconductor device 10 is ultrasonically vibrated.

A wire 30a shown in FIG. 4(a) is normally connected to each of the electrodes 12 and 25 to 28. When the wire 30a is ultrasonically vibrated, the first-stage to fourth-stage wires 31a to 34a are vibrated laterally at the natural frequency f0 between the electrodes 12 and 25 to 27 which are respectively connected to the lower ends of the first-stage to fourth-stage wires 31a to 34a and the electrodes 25 to 28 which are respectively connected to the upper ends thereof. The natural frequency f0 is different depending on the diameter of the wire 30 and the gap a between the electrodes 25 and 26 and between the electrodes 26 and 27, but is often on the order of several tens of Hz in a general semiconductor device 10.

On the other hand, a non-attached wire 30b is not attached to the electrode 26 of the second-stage semiconductor chip 22. Therefore, when the non-attached wire 30b is ultrasonically vibrated, the second-stage wire 32b and the third-stage wire 33b are laterally vibrated at the natural frequency f1 between the electrode 25 of the first-stage semiconductor chip 21 and the electrode 27 of the third-stage semiconductor chip 23. In this example, as shown in FIG. 4(b), since a gap between the electrode 25 and the electrode 27 becomes 2a which is twice the gap a between the electrodes 25 and 26 and between the electrodes 26 and 27, the natural frequency f1 of the third-stage wire 33b and the second-stage wire 32b of the non-attached wire 30b is about a half of f0 and is often on the order of 20 to 30 Hz in a general semiconductor device 10.

Additionally, since the substrate 11 and the semiconductor chips 21 to 24 do not have a portion that is naturally vibrated even when these are ultrasonically vibrated, low-frequency natural vibrations such as those of the wire 30a and the non-attached wire 30b do not occur.

As shown in step S102 of FIG. 3, the control unit 50 captures the video of the semiconductor device 10 ultrasonically vibrated in this way by the camera 45 and stores the captured image in the storage unit as shown in step S103 of FIG. 3. The first-stage to fourth-stage wires 31a to 34a of the normally connected wire 30a are vibrated laterally at the natural frequency of several tens of Hz. The frame rate of the video is 24 to 60 frames per second. Therefore, for example, the images of the first-stage to fourth-stage wires 31a to 34a of one frame become like alternating dot-dash lines on the left side of the center line 39a of the wire 30a in FIG. 4(a) and the images of the previous frame before the one frame become like alternating dot-dash lines on the right side of the center line 39a of the wire 30a in FIG. 4(a).

Next, the control unit 50 reads out the image data of the video stored in the storage unit and calculates a difference Δda between images by comparing the images of the first-stage to fourth-stage wires 31a to 34a of one frame shown in FIG. 4(a) with the images of the first-stage to fourth-stage wires 31a to 34a of the previous frame before the one frame as shown in step S104 of FIG. 3. As shown in FIG. 4(a), in the normal wire 30a, the difference Δda is small. Additionally, this difference Δda becomes an amount which is proportional to the amplitudes of the first-stage to fourth-stage wires 31a to 34a.

On the other hand, the second-stage wire 32b and the third-stage wire 33b of the non-attached wire 30b not attached to the electrode 26 of the second-stage semiconductor chip 22 are greatly vibrated laterally at 20 to 30 Hz. As described above, since the frame rate of the video is 24 to 60 frames per second, for example, the images of the second-stage wire 32b and the third-stage wire 33b of one frame become like alternating dot-dash lines on the left side of the center line 39a of the non-attached wire 30b in FIGS. 4(a) and 4(b) and the images of the previous frame before the one frame become like alternating dot-dash lines on the right side of the center line 39b of the non-attached wire 30b in FIGS. 4(a) and 4(b).

Similarly to the case of the wire 30a, as shown in FIG. 4(b), the control unit 50 calculates a difference Δdb between the images of the second-stage wire 32b and the third-stage wire 33b of one frame and the images of the second-stage wire 32b and the third-stage wire 33b of the previous frame before the one frame. As shown in FIG. 4(b), in the second-stage wire 32b and the third-stage wire 33b of the non-attached wire 30b, the difference Δdb is very large and exceeds a prescribed threshold value ΔS. Additionally, the difference Δdb becomes an amount which is proportional to the amplitudes of the second-stage wire 32b and the third-stage wire 33b.

When the difference Δd between the images of the second-stage wire 32b and the third-stage wire 33b of one frame and the images of the second-stage wire 32b and the third-stage wire 33b of the previous frame before the one frame exceeds the prescribed threshold value ΔS as shown in FIG. 4(b), the control unit 50 makes a determination of YES in step S105 of FIG. 3, causes the routine to proceed to step S106 of FIG. 3, and displays the images of the second-stage wire 32b and the third-stage wire 33b on the display 48 so as to be displayed different from the images of the first-stage to fourth-stage wires 31a to 34a of the normally connected wire 30a.

There are various different display methods. For example, the images of the second-stage wire 32b and the third-stage wire 33b of the non-attached wire 30b are displayed in red or bright white so as to be distinguished from the images of the substrate 11 and the semiconductor chips 21 to 24 or the images of the first-stage to fourth-stage wires 31a to 34a of the normally connected wire 30a.

The inspector can detect the presence and position of the non-attached wire 30b at a glance, for example, since the non-attached wire 30b is displayed in red when seeing the image of the display 48.

When the control unit 50 makes a determination of NO in step S105 of FIG. 3, the control unit returns to step S101 of FIG. 3 and keeps ultrasonically vibrating and capturing the semiconductor device 10.

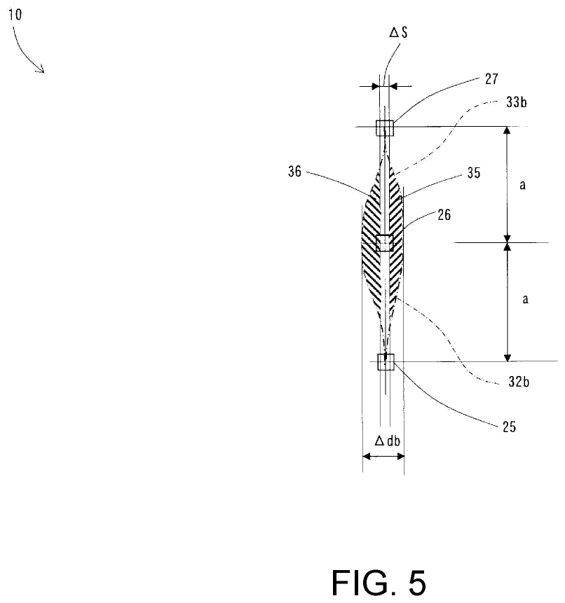

Further, as shown in FIG. 5, when the difference Δdb between the images of the second-stage wire 32b and the third-stage wire 33b of one frame and the images of the second-stage wire 32b and the third-stage wire 33b of the previous frame before the one frame exceeds the prescribed threshold value ΔS, the control unit 50 may display the images of the excess regions 35 and 36 for which the difference Δdb exceeds the prescribed threshold value ΔS in the vibration region of the second-stage wire 32b and the third-stage wire 33b indicated by hatching in FIG. 5 on the display 48 so as to be displayed different from the image of another region. For example, when the excess regions 35 and 36 are displayed in red, a wider region than the images of the second-stage wire 32b and the third-stage wire 33b of the non-attached wire 30b is displayed in red and hence the inspector can more easily detect the non-attached wire 30b.

As described above, the wire non-attachment inspection system 100 of this embodiment uses a principle that the amplitude of the non-attached wire 30b becomes larger than the amplitude of the normally connected wire 30a and the amplitudes of the substrate 11 and the semiconductor chips 21 to 24 when each wire 30 is ultrasonically vibrated by vibrating the semiconductor device 10 with ultrasonic waves. The control unit 50 can display the image of the non-attached wire 30b on the display 48 so as to be distinguished from another image by calculating the difference Δd between the image of one frame of the captured video and the image of the previous frame before the one frame and displaying the image of the non-attached wire 30b for which the difference Δd exceeds the prescribed threshold value ΔS on the display 48 so as to be different from the image of another wire 30. Accordingly, the inspector can detect the non-attached wire 30b by the image of the display 48. Since a difference between the amplitude of the non-attached wire 30b and the amplitude of the normally connected wire 30a is noticeable, the non-attachment of the non-attached wire 30b can be detected with high accuracy. Further, since the images of all wires 30 included in the semiconductor device 10 are acquired by the camera 45 and are also analyzed and displayed on the display 48, the non-attachment of all wires 30 can be inspected in a short time even when the number of the wires 30 increases.

In the description above, an example has been described in which the natural frequency f0 between the electrodes 12 and 25 to 28 of the normal wire 30a is on the order of several tens of Hz, the natural frequency f1 between the electrode 25 and the electrode 27 of the second-stage wire 32b and the third-stage wire 33b of the non-attached wire 30b is on the order of 20 to 30 Hz, the frame rate of the video is 24 to 60 frames per second, and the difference Δd between the image of one frame and the image of the previous frame before the one frame is calculated. However, the previous frame is not limited thereto as long as the frame is before the one frame. For example, when the natural frequencies f0 and f1 of the normal wire 30a and the non-attached wire 30b are lower, the difference Δd between the image of one frame and the image of the frame two or three before may be calculated and compared with the threshold value ΔS. This corresponds to capturing a video at a rate of ½ or ⅓ of the frame rate. Further, the frame rate of the video may be changed depending on the natural frequencies of the normal wire 30a and the non-attached wire 30b and may be set to the frame rate at which the difference Δd is noticeable. In this way, the control unit 50 may calculate the difference Δd by changing the number of frames between one frame and the previous frame or the frame rate of the video. Accordingly, it is possible to noticeably detect the difference Δd by adjusting the timing of the frame of the video that calculates the difference Δd and the natural frequencies f0 and f1 of the normal wire 30a and the non-attached wire 30b.

Further, the control unit 50 may change the frequency of the AC power of the ultrasonic oscillator 40 so that the semiconductor device 10 is ultrasonically vibrated. The natural frequency of the wire 30 changes depending on the length of the wire 30 between the bonding points or the diameter of the wire.

When the gaps between the electrodes 12 and 25 to 28 are respectively different, their natural frequencies are also different. Accordingly, it is possible to effectively detect the non-attachment of each portion of each wire 30 by changing the oscillation frequency of the AC power of the ultrasonic oscillator 40 and ultrasonically vibrating the semiconductor device 10. Further, the same also applies to a case in which one semiconductor device 10 uses the wires 30 having different diameters. Here, the oscillation frequency of the AC power of the ultrasonic oscillator 40 can be freely changed. For example, the sweep may be performed so as to increase the frequency from 10 kHz to 150 kHz, or conversely, the sweep may be performed from a high frequency to a low frequency.

In the above-described wire non-attachment inspection system 100, a case has been described in which the inspector detects the non-attached wire 30b by displaying the image of the non-attached wire 30b on the display 48 so as to be displayed different from another image, but the present invention is not limited thereto. The control unit 50 may determine that there is an image of the non-attached wire 30b for which the difference Δd exceeds the prescribed threshold value ΔS and may display the non-attachment detection of the wire 30 on the display 48 in that case. In this case, for example, the wording of “wire non-attachment detection” or the like may be displayed on the display 48.

Further, when the wire non-attachment detection method is performed by the wire non-attachment inspection system 100, a step of arranging the ultrasonic oscillator 40, the ultrasonic transducer 42, the camera 45, and the display 48, connecting the ultrasonic transducer 42 to the ultrasonic oscillator 40, and connecting the ultrasonic oscillator 40, the camera 45, and the display 48 to the control unit 50 to configure the wire non-attachment inspection system 100 constitutes a preparation step. Then, a step of controlling the ultrasonic oscillator 40 by the control unit 50 and ultrasonically vibrating the substrate 11 with the ultrasonic transducer 42 constitutes an ultrasonic vibration step. Further, steps of capturing the video of the semiconductor device 10 by the control unit 50 and calculating the difference Δd between the images of the frames of the captured video respectively constitute a capturing step and a difference calculation step. Further, a step of displaying the image of the non-attached wire 30b for which the difference Δd exceeds the prescribed threshold value ΔS on the display 48 so as to be displayed different from the image of the normal wire 30a constitutes a display step. Then, a step of detecting the non-attached wire 30b by the inspector based on the image of the display 48 constitutes a non-attachment detection step.

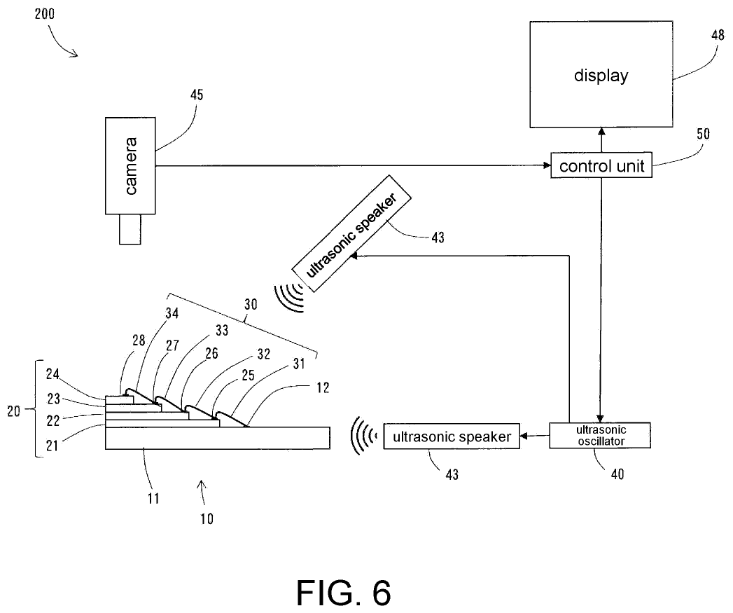

Next, a wire non-attachment inspection system 200 of another embodiment will be described with reference to FIG. 6. The same parts as those described above with reference to FIGS. 1 to 4 are designated by the same reference numerals and the description thereof will be omitted.

As shown in FIG. 6, the wire non-attachment inspection system 200 has a configuration in which the ultrasonic transducer 42 of the wire non-attachment inspection system 100 described with reference to FIGS. 1 to 5 is replaced by an ultrasonic speaker 43 disposed in the periphery of the semiconductor device 10.

The wire non-attachment inspection system 200 can directly and ultrasonically vibrate the wire 30 in addition to the same action and effect as those of the above-described wire non-attachment inspection system 100 and hence more highly accurately detect the non-attachment of the wire 30.

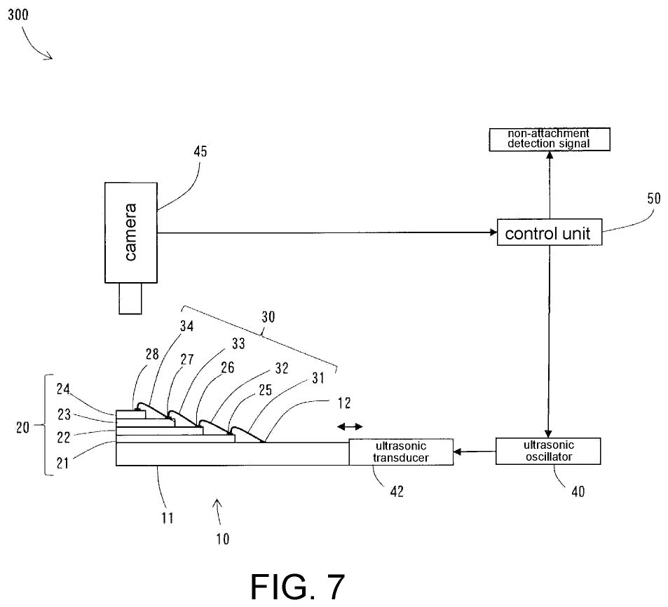

Next, a wire non-attachment detection device 300 of the embodiment will be described with reference to FIG. 7. The same parts as those of the wire non-attachment inspection system 100 of the embodiment described with reference to FIGS. 1 to 5 are designated by the same reference numerals and the description thereof will be omitted. As shown in FIG. 7, the wire non-attachment detection device 300 of the embodiment does not include the display 48 and the control unit 50 calculates the difference Δd between the image of one frame of the video captured by the camera 45 and the image of the previous frame before the one frame and outputs a non-attachment detection signal to the outside when the difference Δd exceeds the prescribed threshold value ΔS.

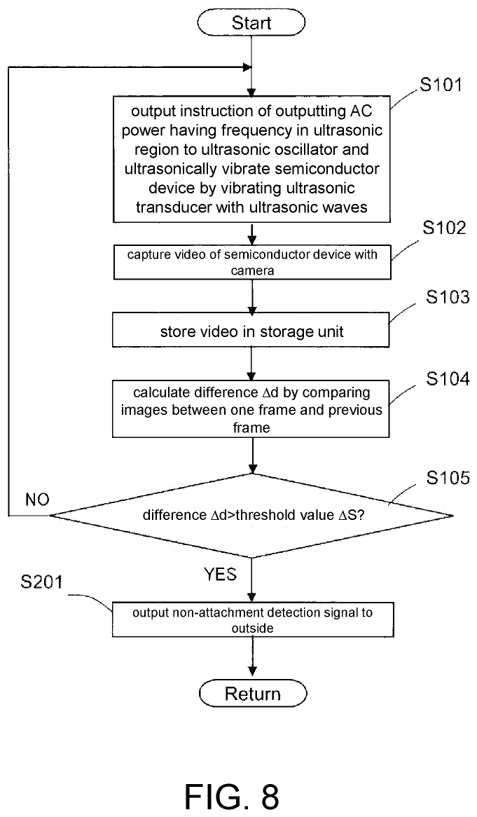

Next, the operation of the wire non-attachment detection device 300 will be described with reference to FIG. 8. The same steps as those of the operation of the control unit 50 of the wire non-attachment inspection system 100 described with reference to FIG. 3 are designated by the same step numbers and the description thereof will be omitted.

As shown in steps S101 to S104 of FIG. 8, the control unit 50 outputs AC power having a frequency in an ultrasonic region from the ultrasonic oscillator 40 so that the substrate 11 of the semiconductor device 10 is ultrasonically vibrated by vibrating the ultrasonic transducer 42 with ultrasonic waves, captures the video of the semiconductor device 10 by the camera 45, stores the image data of the video in the storage unit, and calculates the difference Δd of the image.

When the control unit 50 makes a determination of YES in step S105 of FIG. 8, the control unit causes the routine to proceed to step S201 of FIG. 8 and outputs the non-attachment detection signal to the outside.

The non-attachment detection signal is input from the control unit 50 to various external devices. For example, when the external device is a display device or a warning lamp, the wording of “wire non-attachment detection” may be displayed or the warning lamp may be turned on.

Further, when the external device is a transfer device or the like, the semiconductor device 10 may be removed from the subsequent production line as a defective product when the wire non-attachment detection signal is input from the control unit 50.

Further, the control unit 50 may calculate the number and position of the non-attached wire 30b from the result of analyzing the image and include information on the number and position of the non-attached wire 30b in the non-attachment signal.

Further, when the wire non-attachment detection method is performed by the wire non-attachment detection device 300, a step of arranging the ultrasonic oscillator 40, the ultrasonic transducer 42, and the camera 45, connecting the ultrasonic transducer 42 to the ultrasonic oscillator 40, and connecting the ultrasonic oscillator 40 and the camera 45 to the control unit 50 constitutes a preparation step. Then, a step of controlling the ultrasonic oscillator 40 by the control unit 50 and ultrasonically vibrating the substrate 11 with the ultrasonic transducer 42 constitutes an ultrasonic vibration step. Further, steps of capturing the video of the semiconductor device 10 by the control unit 50 and calculating the difference Δd between the images of the frames of the captured video respectively constitute a capturing step and a difference calculation step. Then, a step of outputting the non-attachment detection signal when the difference Δd exceeds the prescribed threshold value ΔS constitutes a non-attachment detection step.

Additionally, in the above-described embodiments, the semiconductor device 10 which is the inspection target has a configuration in which the semiconductor chips 21 to 24 are laminated and mounted on the substrate 11 in four stages and one wire 30 continuously connects the electrodes 25 to 28 of the semiconductor chips 21 to 24 to the electrode 12 of the substrate 11, but the present invention is not limited thereto. For example, the present invention can be also used to inspect the non-attachment of the wire 30 of the semiconductor device 10 in which one semiconductor chip 21 is mounted on the substrate 11 and the semiconductor chip 21 is connected to the electrode 12 of the substrate 11 by the wire 30.

### REFERENCE SIGNS LIST

10 Semiconductor device
11 Substrate
12, 25 to 27 Electrode
20 Semiconductor element
21 to 24 Semiconductor chip
30, 30a Wire
30b Non-attached wire
31 to 34 First-stage to fourth-stage wires
35, 36 Excess region
39a, 39b Center line
40 Ultrasonic oscillator
42 Ultrasonic transducer
43 Ultrasonic speaker
45 Camera
48 Display
50 Control unit
100, 200 Wire non-attachment inspection system
300 Wire non-attachment detection device

1. A wire non-attachment inspection system of a semiconductor device including a substrate, a semiconductor element mounted on the substrate, and a wire connecting an electrode of the semiconductor element to an electrode of the substrate or connecting one electrode of the semiconductor element to another electrode of the semiconductor element, the wire non-attachment inspection system comprising:
an ultrasonic oscillator;
an ultrasonic vibrator which is connected to the ultrasonic oscillator and ultrasonically vibrates the semiconductor device by power from the ultrasonic oscillator;
a camera which captures a video of the semiconductor device;
a display which displays the video captured by the camera; and
a control unit which adjusts the ultrasonic oscillator and analyzes the video captured by the camera,
wherein the control unit calculates a difference in image between one frame of a captured video and a previous frame before the one frame and displays an image of the wire for which the difference exceeds a prescribed threshold value on the display so as to be displayed different from an image of another wire.

2. The wire non-attachment inspection system according to claim 1,
wherein the control unit displays an image of an excess region for which the difference exceeds the prescribed threshold value in a vibration region of the wire on the display so as to be displayed different from an image of another region.

3. The wire non-attachment inspection system according to claim 1,
wherein the control unit calculates the difference by changing a number of frames between one frame for calculating the difference and a previous frame or a frame rate of a video.

4. The wire non-attachment inspection system according to claim 1,
wherein the control unit ultrasonically vibrates the semiconductor device with the ultrasonic vibrator by changing an oscillation frequency of the ultrasonic oscillator.

5. The wire non-attachment inspection system according to claim 1,
wherein the ultrasonic vibrator is an ultrasonic transducer which is connected to the substrate of the semiconductor device and ultrasonically vibrates the substrate.

6. The wire non-attachment inspection system according to claim 1,
wherein the ultrasonic vibrator is an ultrasonic speaker which is disposed in a periphery of the semiconductor device.

7. A wire non-attachment detection device of a semiconductor device comprising a substrate, a semiconductor element mounted on the substrate, and a wire connecting an electrode of the semiconductor element to an electrode of the substrate or connecting one electrode of the semiconductor element to another electrode of the semiconductor element, the wire non-attachment detection device comprising:
an ultrasonic oscillator;
an ultrasonic vibrator which is connected to the ultrasonic oscillator and ultrasonically vibrates the semiconductor device by power from the ultrasonic oscillator;
a camera which captures a video of the semiconductor device; and
a control unit which adjusts the ultrasonic oscillator and analyzes the video captured by the camera,
wherein the control unit calculates a difference in image between one frame of a captured video and a previous frame before the one frame and outputs a non-attachment detection signal when the difference exceeds a prescribed threshold value.

8. The wire non-attachment detection device according to claim 7,
wherein the control unit calculates the difference by changing a number of frames between one frame for calculating the difference and a previous frame or a frame rate of a video.

9. The wire non-attachment detection device according to claim 7,
wherein the control unit ultrasonically vibrates the semiconductor device with the ultrasonic vibrator by changing an oscillation frequency of the ultrasonic oscillator.

10. The wire non-attachment detection device according to claim 7,
wherein the ultrasonic vibrator is an ultrasonic transducer which is connected to the substrate of the semiconductor device and ultrasonically vibrates the substrate.

11. The wire non-attachment detection device according to claim 7,
wherein the ultrasonic vibrator is an ultrasonic speaker which is disposed in a periphery of the semiconductor device.

12. A wire non-attachment detection method of a semiconductor device comprising a substrate, a semiconductor element mounted on the substrate, and a wire connecting an electrode of the semiconductor element to an electrode of the substrate or connecting one electrode of the semiconductor element to another electrode of the semiconductor element, the wire non-attachment detection method comprising:
a preparation step of preparing an ultrasonic oscillator, an ultrasonic vibrator which is connected to the ultrasonic oscillator and ultrasonically vibrates the semiconductor device by power from the ultrasonic oscillator, a camera which captures a video of the semiconductor device, and a control unit which is connected to the ultrasonic oscillator and the camera;
an ultrasonic vibration step of ultrasonically vibrating the substrate with the ultrasonic vibrator by power from the ultrasonic oscillator;
a capturing step of capturing a video of the ultrasonically vibrated semiconductor device by the camera;
a difference calculation step of calculating a difference in image between one frame of the captured video and a previous frame before the one frame; and
a non-attachment detection step of detecting non-attachment of a wire when the difference exceeds a prescribed threshold value.

13. The wire non-attachment detection method according to claim 12,
wherein the preparation step comprises a step of preparing a display displaying a video captured by the camera and connecting the display to the control unit,
wherein the wire non-attachment detection method further comprises a display step of displaying an image of the wire for which the difference exceeds the prescribed threshold value on the display so as to be displayed different from an image of another wire, and
wherein the non-attachment detection step is to detect non-attachment of the wire based on an image displayed on the display.

14. The wire non-attachment detection method according to claim 13,
wherein the display step is to display an image of an excess region for which the difference exceeds the prescribed threshold value in a vibration region of the wire on the display so as to be displayed different from an image of another region.
